(19) United States
(12) Patent Application Publication
(10) Pub. No.: US 2017/0263680 A1
(43) Pub. Date: Sep. 14, 2017

(54) MAGNETORESISTIVE MEMORY DEVICE AND MANUFACTURING METHOD OF THE SAME

(71) Applicants: KABUSHIKI KAISHA TOSHIBA, Tokyo (JP); SK HYNIX INC., Icheon-si (KR)

(72) Inventors: Kenichi YOSHINO, Seoul (KR); Toshihiko NAGASE, Seoul (KR); Youngmin EEH, Seongnam-si Gyeonggi-do (KR); Daisuke WATANABE, Seoul (KR); Kazuya SAWADA, Seoul (KR); Makoto NAGAMINE, Seoul (KR); Won Joon CHOI, Gwanak-gu Seoul (KR); Guk Cheon KIM, Yeoju-si Gyeonggi-do (KR); Yang Kon KIM, Gyeyang-gu Incheon-si (KR); Jong Koo LIM, Icheon-si Gyeonggi-do (KR)

(73) Assignees: KABUSHIKI KAISHA TOSHIBA, Tokyo (JP); SK HYNIX INC., Icheon-si (KR)

(21) Appl. No.: 15/268,497

(22) Filed: Sep. 16, 2016

Related U.S. Application Data
(60) Provisional application No. 62/308,163, filed on Mar. 14, 2016.

(51) Int. Cl. H01L 27/24; H01L 43/12; H01L 45/00; H01L 43/02

(52) U.S. Cl. CPC H01L 27/24; H01L 43/02; H01L 43/12; H01L 45/1608; H01L 45/1253; H01L 45/1233

(57) ABSTRACT

According to one embodiment, a magnetoresistive memory device includes an electrode, a first layer which is provided on the electrode and includes an amorphous portion in at least a part of an electrode side, and a magnetoresisive element provided on the first layer.

### CROSS-REFERENCE TO RELATED APPLICATIONS

This application claims the benefit of U.S. Provisional Application No. 62/308,163, filed Mar. 14, 2016, the entire contents of which are incorporated herein by reference.

### FIELD

Embodiments described herein relate generally to a magnetoresistive memory device and a manufacturing method of the same.

### BACKGROUND

Recently, a high-capacity magnetoresistive random access memory (MRAM) using a magnetic tunnel junction (MTJ) element, has been raising expectations and drawing attention. The MTJ element comprises two magnetic layers across an intervening tunnel barrier layer. One of the magnetic layers is a magnetization fixed layer (reference layer) in which the magnetization direction is fixed such that it does not change. The other one is a magnetization free layer (storage layer) in which the magnetization direction is easily reversed.

### BRIEF DESCRIPTION OF THE DRAWINGS

FIG. 1 is a cross-sectional view showing an element structure of a magnetoresistive memory device according to a first embodiment.

FIGS. 2A to 2C are schematic diagrams showing the change in concentration of an additive in a buffer layer.

FIG. 3 is a cross-sectional view showing an element structure of a magnetoresistive memory device according to a second embodiment.

FIGS. 4A to 4G are schematic diagrams showing the change in concentration of an additive in a buffer layer.

FIG. 5 is a cross-sectional view showing an element structure of a magnetoresistive memory device according to a third embodiment.

FIG. 6 is a circuit structural diagram showing a memory cell array of an MRAM according to a fourth embodiment.

FIG. 7 is a cross-sectional view showing the structure of the memory cell portion of the MRAM of FIG. 6.

FIGS. 8A to 8C are cross-sectional views showing the process for manufacturing the memory cell portion of FIG. 7.

### DETAILED DESCRIPTION

In general, according to one embodiment, a magnetoresistive memory device comprises an electrode, a first layer which is provided on the electrode and includes an amorphous portion in at least a part of an electrode side, and a magnetoresistive element provided on the first layer.

Embodiments will be described hereinafter with reference to the accompanying drawings.

### First Embodiment

FIG. 1 is a cross-sectional view showing the structure of a memory cell portion of a magnetoresistive memory device according to a first embodiment.

As a first layer, two buffer layers 21 and 22 are provided on a bottom electrode (BEC) 10. Specifically, the first buffer layer (BL1 [first conductive layer]) 21 is provided on the bottom electrode 10. The second buffer layer (BL2 [second conductive layer]) 22 is provided on the first buffer layer 21. The number of layers included in the first layer is not limited to two and may be three or more.

The bottom electrode 10 comprises Ta, W, titanium nitride (TiN) or tantalum nitride (TaN). Buffer layers 21 and 22 contain Al, Be, Mg, Ca, Sr, Ba, Sc, Y, La, Si, Zr, Hf, W, Cr, Mo, Nb, Ti, Ta, V, etc., as the base material, and contain B or C as the additive.

Further, as the base material, metal with a high melting point is preferably used. This structure can prevent the diffusion of the materials of the buffer layers to a magnetic layer, thereby preventing degradation of characteristics of the MTJ element, for example, the MR ratio. Metal with a high melting point is a material having a melting point higher than that of Fe and Co, and is, for example, Zr, Hf, W, Cr, Mo, Nb, Ti, Ta or V. The same base material and additive are preferably used for buffer layers 21 and 22. However, different base materials and additives may be used for buffer layers 21 and 22. Further, both B and C may be contained as the additive.

Buffer layers 21 and 22 are preferably easy to oxidize. In consideration of two factors, difficulty of diffusion and easiness of oxidation, Zr, Hf and Ta are particularly desirable.

The concentration of additive in buffer layers 21 and 22 is high on the bottom electrode 10 side and is lower on the underlayer 23 side. Thus, the concentration of additive is high in the first buffer layer 21. The first buffer layer 21 is amorphous. The concentration of additive is lower in the second buffer layer 22. The second buffer layer 22 is crystalline. The change in concentration of additive in buffer layers 21 and 22 has a slope continuous in a direction perpendicular to the surface of the substrate (in other words, in the thickness direction of buffer layers 21 and 22). The concentration of additive is greater than or equal to 2% and less than or equal to 65% at the interface with the bottom electrode 10, and is less than 10% at the interface with the underlayer 23.

To make buffer layer 21 amorphous, the concentration of additive in buffer layer 21 must be greater than or equal to 2%, and is preferably greater than 10%. However, if the concentration of additive in buffer layer 21 exceeds 65%, the additive is deposited as it is not distributed uniformly in buffer layer 21. This situation is not desirable. Note that the percentage concentration of additive refers to at % unless otherwise stated.

Buffer layer 21 need not be amorphous as a whole and may be amorphous near the interface with the bottom electrode 10. Buffer layer 21 may be partially amorphous.

To improve the crystallinity of buffer layer 22, the concentration of additive in buffer layer 22 is preferably less than 10%. The change in concentration of additive need not be continuous and may be discontinuous between the first buffer layer 21 and the second buffer layer 22.

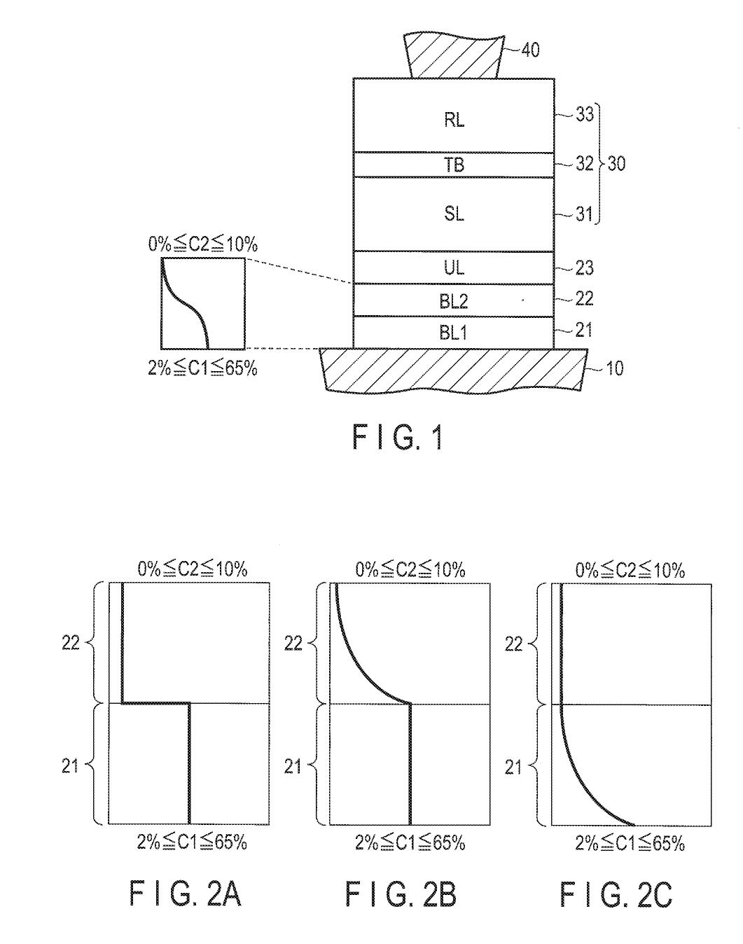

FIG. 2A shows a case where the concentration of additive is constant in both buffer layer 21 and buffer layer 22. FIG. 2B shows a case where the concentration of additive is constant in buffer layer 21, and the concentration of additive is changed in buffer layer 22. FIG. 2C snows a case where the concentration of additive is changed in buffer layer 21, and the concentration of additive is constant in buffer layer 22. In all of the cases, an amorphous portion can be formed in buffer layer 21, and the crystallinity of the surface of buffer layer 22 can be enhanced.

In consideration of the above description, the concentration of additive may be determined as follows. The concentration (C2) of additive at the interface between buffer layer 22 and the underlayer 23 is lower than the concentration (C1) of additive at the interface between buffer layer 21 and the bottom electrode 10. Further, the concentration of additive at the interface between buffer layer 21 and buffer layer 22 is greater than or equal to C2 and less than or equal to C1. In addition, concentration C1 and concentration C2 satisfy 2%≦C1≦65% and 0%≦C2≦10%.

Buffer layers 21 and 22 are formed by, for example, sputtering. The concentration of base material and additive can be adjusted at the time of sputtering by using two targets. One of the targets contains the element of the base material, and the other one contains the element of the additive. Alternatively, sputtering may be performed by using only one target containing both the base material and the additive. After forming a film containing the base material, the additive may be introduced by ionic implantation, etc.

The underlayer (UL [second layer]) 23 is provided on the second buffer layer 22. Since buffer layer 22 is crystalline, the crystallinity of the underlayer 23 is good.

The underlayer 23 is a nitrogenous compound or an oxygen compound such as magnesium oxide (MgO), magnesium nitride (MgN), zirconium nitride (ZrN), niobium nitride (NbN), silicon nitride (SiN), aluminum nitride (AlN), hafnium nitride (HfN), tantalum nitride (TaN), tungsten nitride (WN), chromium, nitride (CrN), molybdenum nitride (MoN), titanium, nitride (TiN) or vanadium nitride (VN). The underlayer 23 may be a compound thereof. The underlayer 23 is not limited to a binary compound containing two elements, and may be a ternary compound containing three elements such as titanium aluminum nitride (AlTiN).

A nitrogenous compound and an oxygen compound prevent an increase in the damping constant of the magnetic layer which is in contact with the compounds. Thus, a write current can be reduced. Moreover, it is possible to prevent the diffusion of the material of the underlayer to the magnetic layer and the degradation of the MR ratio by using a nitrogenous compound or an oxygen compound comprising metal with a high melting point. Metal with a high melting point is a material having a melting point higher than that of Fe and Co, and is, for example, Zr, Hf, W, Cr, Mo, Nb, Ti, Ta or V. When the resistance of the underlayer 23 is high, for example, the resistance is preferably decreased in comparison with the resistance of a tunnel barrier layer 32 by adjusting the film thickness of the underlayer 23.

An MTJ element (magnetoresistive element) 30 including a storage layer (SL [first magnetic layer]) 31, the tunnel barrier layer (TB [nonmagnetic layer]) 32 and a reference layer (RL [second magnetic layer]) 33 is provided on the underlayer 23.

The storage layer 31 is a ferromagnetic layer which has magnetic anisotropy perpendicular to the surface of the film. The magnetization direction of the storage layer 31 is variable. For example, the storage layer 31 comprises cobalt iron boron (CoFeB) or iron boride (FeB). The tunnel barrier layer 32 comprises, for example, MgO. The reference layer 33 is a ferromagnetic layer which has magnetic anisotropy perpendicular to the surface of the film. The magnetization direction of the reference layer 33 is fixed. For example, the reference layer 33 comprises cobalt platinum (CoPt), cobalt nickel (CoNi) or cobalt palladium (CoPd). The reference layer 33 may be a multilayer film such as Co/Pt, Co/Pd or Co/Ni.

A top electrode (TEC) 40 is provided on the MTJ element 30. The top electrode 40 is W, Ta, Ti, tantalum nitride (TaN) or titanium nitride (TiN).

Thus, in the present embodiment, the amorphous first buffer layer 21 and the crystalline second buffer layer 22 are provided on the bottom electrode 10. The MTJ element 30 is provided above buffer layers 21 and 22 via the underlayer 23.

If the crystalline buffer layer 22 is provided directly on the bottom electrode 10, buffer layer 22 is affected by the roughness or crystalline orientation of the bottom electrode 10. This situation is not desirable. In terms of the influence of roughness, the crystalline buffer layer 22 should not be provided directly on the bottom electrode 10 even when the bottom electrode 10 is not crystalline.

When the crystalline buffer layer 22 is provided above the bottom electrode 10 via the amorphous buffer layer 21, buffer layer 22 can exhibit a good crystallinity in the original crystalline orientation without an influence to be caused by the crystalline orientation of the bottom electrode 10. Because of the intervention of the amorphous layer, it is possible to enhance the crystallinity of buffer layer 22 without relying on the characteristics of the bottom electrode 10 such as roughness and crystalline orientation.

When the crystallinity of buffer layer 22 is improved, the crystallinity of the underlayer 23 provided on buffer layer 22 is improved. The improvement of the crystallinity of the underlayer 23 allows the underlayer 23 to be smoother and prevents the diffusion of the elements contained in the underlayer 23 and the layers under the underlayer 23 to the magnetic layers. In this manner, the magnetic anisotropy of magnetic layers 31 and 33 can be improved. This configuration leads to improvement of the magnetic characteristics of the MTJ element 30. Thus, the magnetic characteristics of the MTJ element 30 can be improved by providing the amorphous layer between the bottom electrode 10 and magnetic layer 31.

The change in the magnetic characteristics was examined regarding a case where a two-layered structure including buffer layers 21 and 22 was employed like the present embodiment, and a case where a single-layered structure including only buffer layer 22 was employed. As a result, the dispersion of the magnetic characteristics is less when the two-layered structure was employed for the buffer layer than when the single-layered structure was employed for the buffer layer.

Thus, the buffer layer of the present embodiment has a stacked layer structure including the amorphous first buffer layer 21 containing a large amount of additive B or C and the crystalline second buffer layer 22 containing a smaller amount of additive. In this way, it is possible to improve the smoothness or crystallinity of the underlayer 23. Thus, for example, the smoothness of magnetic layers 31 and 33 provided on the underlayer 23 can be improved. As a result, the magnetic characteristics of the MTJ element 30 can be improved.

Moreover, metal having a high melting point is used for the base materials of buffer layers 21 and 22. With this structure, the diffusion of the materials of the buffer layers to the magnetic layers can be prevented. Thus, it is possible to prevent degradation of the MR ratio and short-circuiting on a side surface of the MTJ element. Use of Zr, Hf, Ta, etc., which are difficult to diffuse and easy to oxidize also prevents degradation of the MR ratio and short-circuiting in the MTJ element.

### Second Embodiment

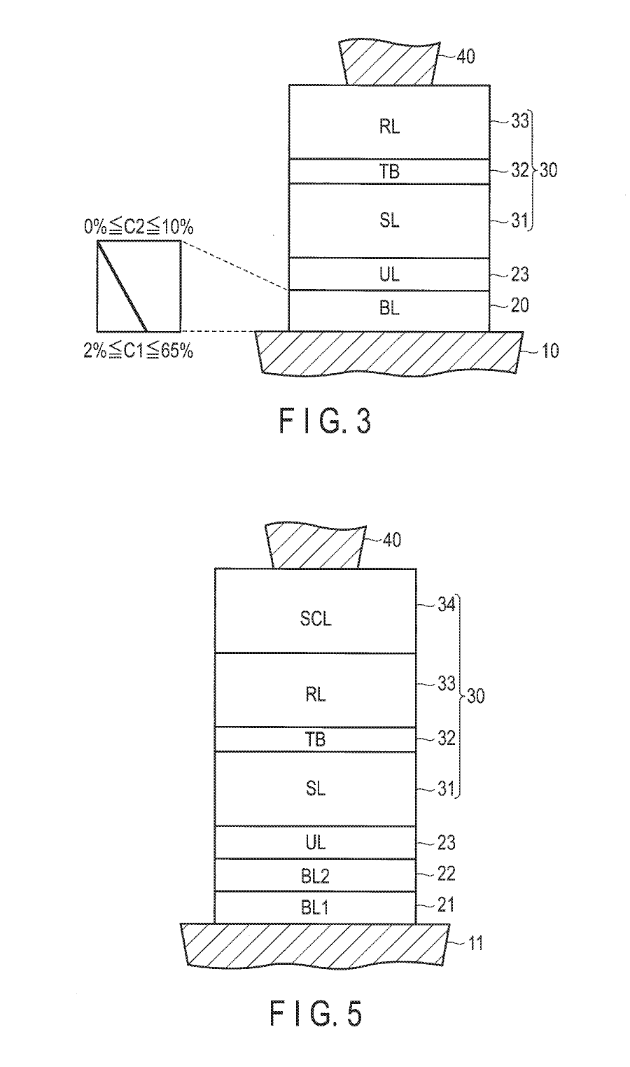

FIG. 3 is a cross-sectional view showing an element structure of a magnetoresistive memory device according to a second embodiment. Elements which are identical to those of FIG. 1 are denoted by the same reference numbers. Thus, the detailed explanation of such elements may be omitted.

The present embodiment is different from the first embodiment explained, above in respect that the buffer layer is formed so as to have a single-layered structure, and the concentration of additive in the buffer layer is changed.

A buffer layer (first layer) 20 is provided on a bottom electrode 10. An underlayer (second layer) 23 is provided on the buffer layer 20. In a manner similar to that of the first embodiment, the buffer layer 20 comprises a base material such as Zr, Hf, W, Cr, Mo, Nb, Ti, Ta or V, and an additive such as B or C. The concentration of additive B or C in the buffer layer 20 is changed continuously in the thickness direction of the buffer layer 20. The concentration of additive B or C in the buffer layer 20 is high on the bottom electrode 10 side and is lower on the underlayer 23 side. The concentration of additive is greater than or equal to 2% and less than or equal to 65% at the interface with the bottom electrode 10, and is less than 10% at the interface with the underlayer 23. Thus, the buffer layer 20 is amorphous near the interface with the bottom electrode 10, and is crystalline near the interface with the underlayer 23.

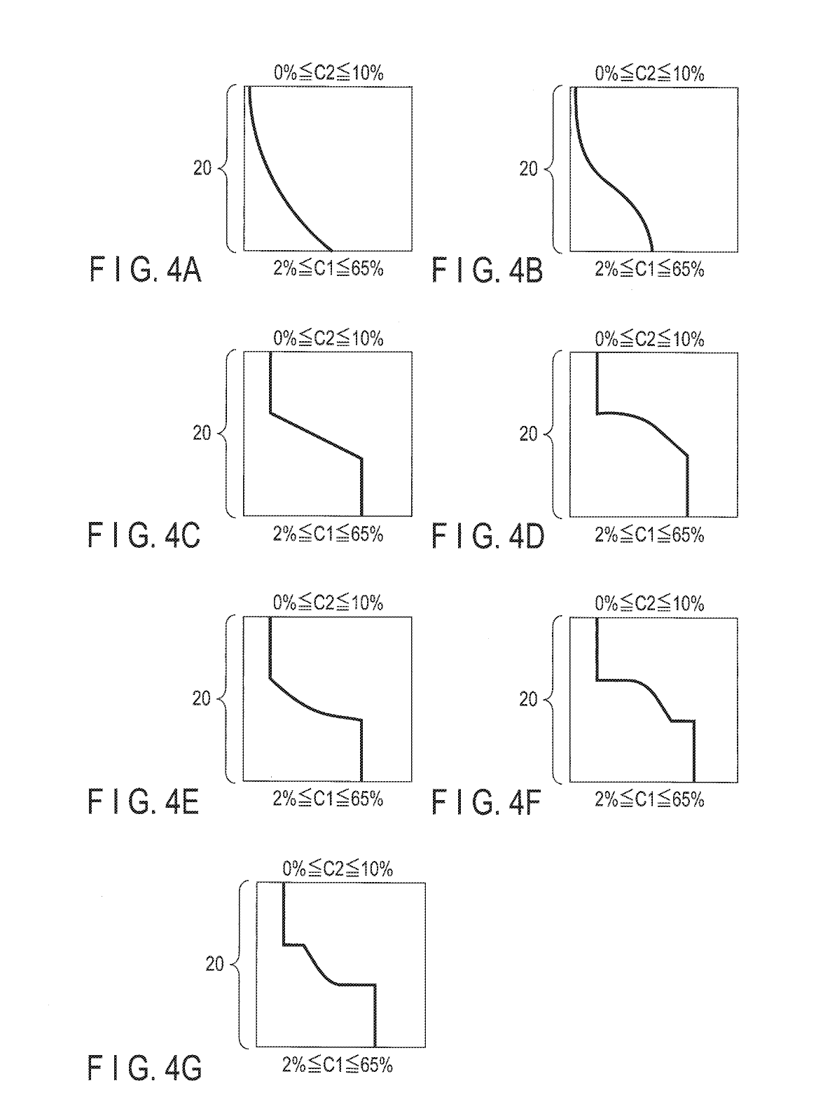

The concentration of additive in the buffer layer 20 need not be changed linearly and may be changed in a curved line as shown in FIG. 4A and FIG. 4B. The concentration of additive may be changed in a stepwise manner. As shown in FIGS. 4C to 4G, a part of the change in the concentration of additive may be stepwise, and a part of the change in the concentration of additive may be continuous. To form the buffer layer 20 in which the concentration of additive is changed as described above, a target containing only the base material and a target containing only the additive may be used. Further, the amount of sputtering of the target containing only the additive may be decreased during sputtering.

Thus, in the present embodiment, the concentration of additive in the buffer layer 20 is high on the bottom electrode 10 side and is lower on the underlayer 23 side. In this manner, the buffer layer 20 is amorphous near the interface with the bottom electrode 10, and is crystalline near the interface with the underlayer 23. With this structure, the crystallinity of the underlayer 23 can be improved without an influence to be applied to the buffer layer 20 by the roughness or crystalline orientation of the bottom electrode 10. It is possible to enhance the magnetic anisotropy of magnetic layers 31 and 33 and obtain an effect similar to that of the first embodiment.

In a manner similar to that of the first embodiment, an amorphous region in which the concentration of additive is high may be provided in a part of the underlayer 23. Because of the amorphous region, the magnetic layers are less affected by the bottom electrode 10.

### Third Embodiment

FIG. 5 is a cross-sectional view showing an element structure of a magnetoresistive memory device according to a third embodiment. Elements which are identical to those of FIG. 1 are denoted by the same reference numbers. Thus, the detailed explanation of such elements may be omitted.

The present embodiment is different from the first embodiment explained above in respect that a shift canceling layer is newly provided. A shift canceling layer (SCL) 34 for canceling or reducing a stray magnetic field is provided on a reference layer 33 of an MTJ element 30. A top electrode 40 is provided on the shift canceling layer 34.

As the material of the shift canceling layer 34, for example, cobalt platinum (CoPt), cobalt nickel (CoNi) or cobalt palladium (CoPd) can be used. The shift canceling layer 34 may be a multilayer film such as Co/Pt, Co/Pd or Co/Ni.

A buffer layer is provided so as to have a stacked layer structure including a first buffer layer 21 and a second buffer layer 22. The first buffer layer 21 is amorphous and contains a large amount of additive B or C. The second buffer layer 22 is crystalline and contains a smaller amount of additive. With this structure, the crystallinity of an underlayer 23 can be improved. The magnetic anisotropy of magnetic layers 31 and 33, etc., provided on the underlayer 23 can be improved. Thus, an effect similar to that of the first embodiment can be obtained.

In the present embodiment, the shift canceling layer 34 is provided. This structure enables a stray magnetic field to be canceled or reduced, thereby further improving the magnetic characteristics.

The structure in which the shift canceling layer 34 is provided like the present embodiment can be applied to the example in which a buffer layer 20 is formed so as to have a single-layered structure like the second embodiment.

### Fourth Embodiment

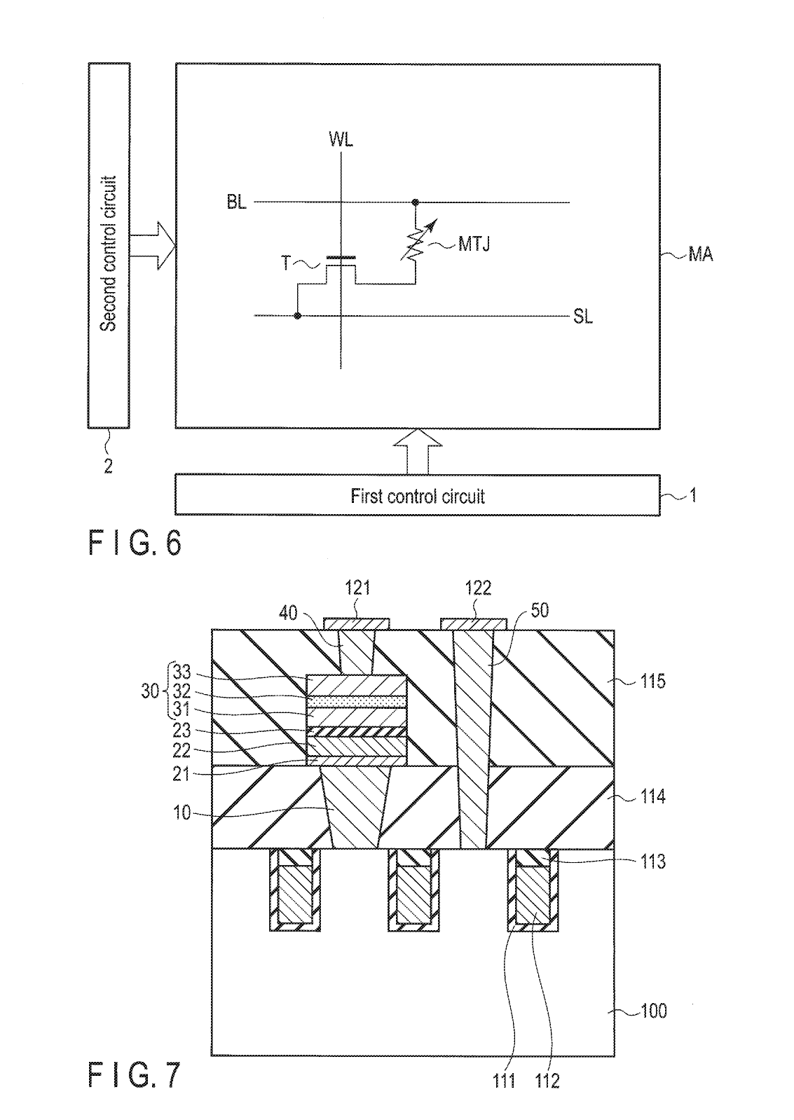

FIG. 6 is a circuit structural diagram showing a memory cell array of an MRAM according to a fourth embodiment. In this embodiment, the magnetoresistive element of the first embodiment explained above is used as each memory cell of the memory cell array.

Each memory cell of the memory cell array MA comprises a series connector for an MTJ element as a magnetoresistive element and a switching element (for example, a field effect transistor [FET]) T. One end of the series connector (in other words, one end of the MTJ element) is electrically connected to a bit line BL. The other end of the series connector (in other words, one end of the switching element T) is electrically connected to a source line SL.

The control terminal of the switching element T, for example, the gate electrode of the FET, is electrically connected to a word line WL. The potential of the word line WL is controlled by a first control circuit 1. The potentials of the bit line BL and the source line SL are controlled by a second control circuit 2.

FIG. 7 is a cross-sectional view showing the structure of the memory cell portion using the magnetoresistive element according to the present embodiment.

A MOS transistor for switching is provided in the surface portion of an Si substrate 100. An interlayer insulating film 114 comprising, for example, SiO₂ is provided on the MOS transistor. The transistor has a buried-gate structure in which a gate electrode 112 is buried in a groove provided on the substrate 100 via a gate insulating film 111. The gate electrode 112 is buried halfway in the groove. A protective insulating film 113 comprising, for example, SiN is provided on the gate electrode 112. A source/drain region (not shown) is provided on both sides of the buried-gate structure by diffusing p-type or n-type impurities to the substrate 100.

The structure of the transistor portion is not limited to a buried-gate structure. For example, a gate electrode may be provided on the surface of the Si substrate 100 via a gate insulating film. The transistor portion can have any structure as long as it functions as a switching element.

A contact hole for connection with the drain of the transistor is provided in interlayer insulating film 114. A bottom electrode (BEC) 10 is buried in the contact hole. The bottom electrode 10 comprises, for example, Ta.

In a manner similar to that of the first embodiment, an amorphous first buffer layer 21, a crystalline second buffer layer 22 and an underlayer 23 are provided on the bottom electrode 10. An MTJ element 30 in which a tunnel barrier layer 32 is interposed between two ferromagnetic layers 31 and 33 is provided on the underlayer 23.

An interlayer insulating film 115 comprising SiO₂, etc., is provided on the substrate where the MTJ element 30 is provided. A contact plug (TEC) 40 connected to the reference layer 33 of the MTJ element 30 is buried in interlayer insulating film 115. A contact plug 50 connected to the source of the transistor portion penetrates interlayer insulating film 115 and interlayer insulating film 114. Thus, contact plug 50 is buried. An interconnect (BL) 121 connected to contact plug 40 and an interconnect (SL) 122 connected to contact plug 50 are provided on interlayer insulating film 115.

In a manner similar to that of the first embodiment explained above, in this structure, it is possible to enhance the crystallinity of the underlayer 23 without an influence to be applied to the buffer layer 22 by the roughness or crystalline orientation of the bottom electrode 10 since two buffer layers are provided. Thus, the magnetic characteristics of the MTJ element 30 can be improved.

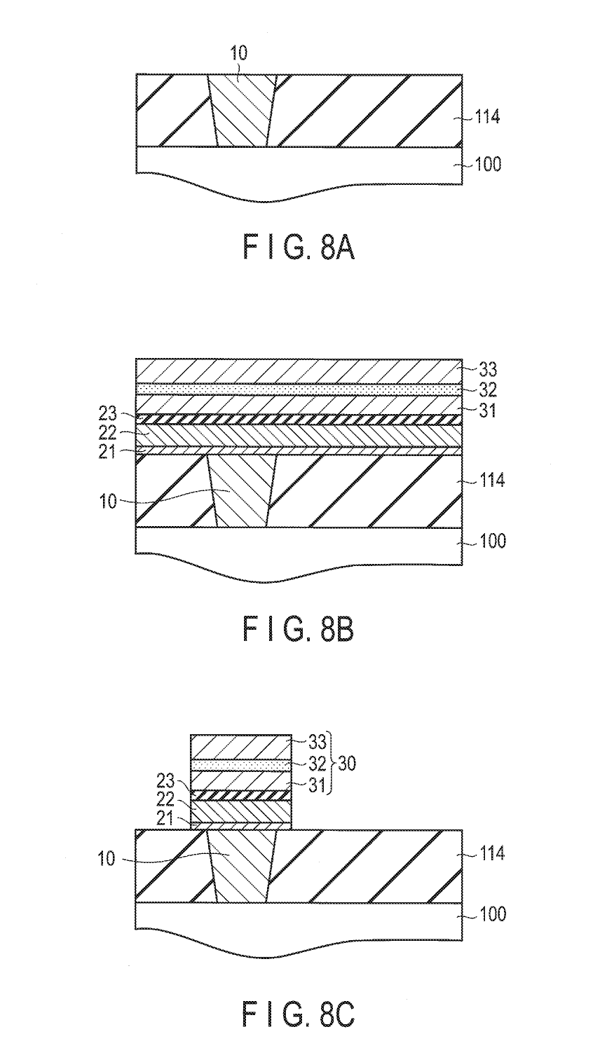

Now, a method of manufacturing the memory cell portion of FIG. 7 is explained with reference to FIGS. 8A to 8C.

As shown in FIG. 8A, the MOS transistor for switching (not shown) having a buried-gate structure is formed in the surface portion of the Si substrate 100. Subsequently, interlayer insulating film 114 comprising SiO₂, etc., is deposited on the Si substrate 100 by a CVD method. Subsequently, the contact hole for connection with the drain of the transistor is formed on interlayer insulating film 114. Subsequently, the bottom electrode (BEG) 10 comprising crystalline Ta is buried in the contact hole. Specifically, a Ta film is deposited on interlayer insulating film 114 by sputtering, etc., so as to fill the contact hole. Subsequently, the Ta film on the interlayer insulating film is removed by chemical mechanical etching (CMP). In this way, the Ta film remains only in the contact hole.

Subsequently, as shown in FIG. 8B, the first buffer layer 21 is formed by applying DC-sputtering to the target. The first buffer layer 21 is amorphous. Subsequently, DC-sputtering is applied to the target, thereby forming the second buffer layer 22 on the first buffer layer 21. The second buffer layer 22 is crystalline.

The first and second buffer layers 21 and 22 which are different in crystallinity may be formed by changing the sputtering target. For example, a common base material may be used. When the first buffer layer 21 is formed, a target containing a large amount of additive B or C may be used. When the buffer layer 22 is formed, a target containing a smaller amount of additive B or C may be used.

By merely changing the sputtering target in this way, the first and second buffer layers 21 and 22 which are different in crystallinity can be formed. Alternatively, the first and second buffer layers 21 and 22 may be formed by using a target formed by only the base material as explained above. A required amount of additive may be added to each buffer layer by ionic implantation.

Subsequently, the underlayer 23 is formed on the buffer layer 22. Subsequently, the storage layer 31, the tunnel barrier layer 32 and the reference layer 33 are formed on the underlayer 23. Thus, a stacked layer structure for forming an MTJ element is formed such that the nonmagnetic tunnel barrier layer is interposed between the ferromagnetic layers.

Subsequently, as shown in FIG. 8C, the MTJ element 30 is formed by processing the above stacked layer portions 21, 22, 23, 31, 32 and 33 into a cell pattern. Specifically, a mask having a cell pattern is formed on the reference layer 33. Selective etching is applied by chemical dry etching (CDE), reactive ion etching (RIE), etc., such that the stacked layer portions remain on the bottom electrode 10 in an island-shape.

Subsequently, interlayer insulating film 115 is formed. Subsequently, contact plugs 40 and 50 are formed. Further, interconnects 121 and 122 are formed. In this manner, the structure shown in FIG. 7 is obtained.

### Modification Example

The present invention is not limited to the above embodiments.

In the present embodiment, the storage layer of the MTJ element is provided on the substrate side. However, for example, the position of the storage layer may be interchanged with that of the reference layer. Specifically, the reference layer may be provided on the substrate side, and the storage layer may be provided on a side opposite to the substrate side. The magnetoresistive element is not limited to an MTJ element. Any structure may be employed as long as the resistance is changed by magnetism.

The base material of the buffer layer is not limited to one element. A plurality of elements may be used from the elements explained above. The additive of the buffer layer is not limited to one of B and C. Both B and C may be added.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A magnetoresistive memory device comprising:
an electrode;
a first layer which is provided on the electrode and includes an amorphous portion in at least a part of an electrode side; and
a magnetoresistive element provided on the first layer.

2. The device of claim 1, further comprising
a second layer provided between the first layer and the magnetoresistive element, wherein
the first layer contains at least one of Zr, Hf and Ta as a base material, and contains at least one of B and C as an additive, and
a concentration of the additive on a second layer side in the first layer is less than a concentration of the additive on an the electrode side in the first layer.

3. The device of claim 1, wherein
the first layer includes a crystalline portion on a magnetoresistive element side.

4. The device of claim 2, wherein
the concentration of the additive in the first layer is changed continuously in a thickness direction of the first layer.

5. The device of claim 2, wherein
the concentration of the additive in the first layer is changed in a stepwise manner in a thickness direction of the first layer.

6. The device of claim 2, wherein
the second layer is crystalline.

7. The device of claim 1, wherein
a size of a bottom surface of the electrode is different from a size of an upper surface of the first layer.

8. The device of claim 1, wherein
the first layer comprises a first conductive layer provided on the electrode side, and a second conductive layer provided on the first conductive layer,
the first and second conductive layers contain at least one of B and C as an additive, and
a concentration of B or C in the first conductive layer is higher than a concentration of B or C in the second conductive layer.

9. The device of claim 8, wherein
the first and second conductive layers contain at least one of Zr, Hf and Ta as a base material.

10. The device of claim 8, wherein
the concentration of B or C in the first or second conductive layer is constant in a thickness direction of the first and second conductive layers.

11. The device of claim 8, wherein
the concentration of B or C in the first or second conductive layer is changed continuously in a thickness direction of the first and second conductive layers.

12. The device of claim 8, wherein
the first conductive layer is amorphous, and the second conductive layer and the second layer are crystalline.

13. The device of claim 1, wherein
the magnetoresistive element has a stacked layer structure comprising a first magnetic layer, a second magnetic layer and a nonmagnetic layer provided, between the first and second magnetic layers.

14. The device of claim 13, wherein
the first magnetic layer or the second magnetic layer includes a crystalline substance.

15. The device of claim 1, further comprising
a substrate on which a transistor for switching is provided, wherein
the electrode is provided on the substrate and is connected to a part of the transistor.

16. A method of manufacturing a magnetoresistive memory device, the method comprising:
forming a first layer on an electrode, the first layer containing at least one of Zr, Hf and Ta as a base material, containing at least one of B and C as an additive, and containing the additive more on an electrode side than on an opposite side of the electrode;
forming a second layer on the first layer; and
forming a magnetoresistive element, on the second layer.

17. The method of claim 16, wherein
the first layer is amorphous on the electrode side, the first layer is crystalline on a second layer side, and
the second layer is crystalline.

18. The method of claim 16, wherein
a concentration of the additive in the first layer is changed continuously or in a stepwise manner in a thickness direction of the first layer.

19. The method of claim 16, wherein
the forming the first layer includes forming a first conductive layer on the electrode, and forming a second conductive layer on the first conductive layer, and
the second conductive layer contains the additive less than the first conductive layer.
